(19) United States
(12) Patent Application Publication
(10) Pub. No.: US 2011/0146758 A1
(43) Pub. Date: Jun. 23, 2011

(54) REFLECTING MULTILAYER ENCAPSULANT

(75) Inventors: Yves M. Trouilhet, Vesenaz (CH); Mark S. Jacobson, Solon, OH (US)

(73) Assignee: E. I. DU PONT DE NEMOURS AND COMPANY, Wilmington, DE (US)

(21) Appl. No.: 12/825,796

(22) Filed: Jun. 29, 2010

Related U.S. Application Data
(60) Provisional application No. 61/221,280, filed on Jun. 29, 2009.

(51) Int. Cl. H01L 31/048; H01L 31/0203; H01L 31/0256; H01L 31/036

(52) U.S. Cl. 136/249; 136/259; 136/251; 136/258

(57) ABSTRACT

A solar cell module comprises a solar cell assembly and a reflecting back encapsulant that is laminated to the back non-sun-facing side of the solar cell assembly. The reflecting back encapsulant comprises a co-extrusion or extrusion coated multilayer sheet, and the multilayer sheet comprises a reflecting layer, a first tie layer and optionally a second tie layer that are co-extruded or extrusion coated on the reflecting layer. The multilayer sheet has a total thickness of about 2 to about 50 mil (about 51 to about 1270 μm). The tie layer(s) comprise polymeric material(s) that have a melting temperature of about 80° C. to about 165° C. and an adhesion to glass of at least about 30 lb/inch when measured with the T-peel test. The reflecting layer has a thickness of about 1 to about 35 mil (about 25 to about 889 μm); comprises a polymeric material having a melting temperature between 80° C. and 165° C.; and further comprises about 4 to about 90 wt %, based on the total weight of the reflecting layer composition, of a filler having a refractive index above 1.6 and a mean particle size of 0.1 to 20 μm.

### CROSS-REFERENCE TO RELATED APPLICATION

This application claims priority to U.S. Provisional Appln. No. 61/221,280, filed on Jun. 29, 2009, which is incorporated herein by reference in its entirety.

### FIELD OF THE INVENTION

The invention is directed to a reflecting multilayer encapsulant for solar cell modules. In particular, a reflecting layer comprising a polymeric material and at least 25% of a filler having an index of refraction higher than 1.4 or 1.6 is co-extruded or extrusion coated on at least one side with a tie layer.

### BACKGROUND OF THE INVENTION

Several patents and publications are cited in this description in order to more fully describe the state of the art to which this invention pertains. The entire disclosure of each of these patents and publications is incorporated by reference herein.

Because solar cells provide a sustainable energy resource, their use is rapidly expanding. Solar cells can typically be categorized into two types based on the light absorbing material used, i.e., bulk or wafer-based solar cells and thin film solar cells.

Monocrystalline silicon (c-Si), poly- or multi-crystalline silicon (poly-Si or mc-Si) and ribbon silicon are the materials used most commonly in forming the more traditional wafer-based solar cells. Solar cell modules derived from wafer-based solar cells often comprise a series of about 180 to about 240 μm thick self-supporting wafers (or cells) that are soldered together and electrically connected. Such a panel of solar cells, along with a layer of conductive paste and/or connecting wires deposited on its surface, may be referred to as a solar cell assembly. The solar cell assembly may be encapsulated by, sandwiched between, or laminated between polymeric encapsulants. The resulting structure may be further sandwiched between two protective outer layers (i.e., front sheet and back sheet) to form a weather resistant module. The protective outer layers may be formed of glass, metal sheets or films, or plastic sheets or films. In general, however, the outer layer that faces to the sunlight needs to be sufficiently transparent to allow photons reach the solar cells.

In the increasingly important alternative, thin film solar cells, the commonly used materials include amorphous silicon (a-Si), microcrystalline silicon (μc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, organic semiconductors, etc. By way of example, thin film solar cells are described in e.g., U.S. Pat. Nos. 5,507,881; 5,512,107; 5,948,176; 5,994,163; 6,040,521; 6,123,824; 6,137,048; 6,288,325; 6,258,620; 6,613,603; and 6,784,301; and U.S. Patent Publication Nos. 20070298590; 20070281090; 20070240759; 20070232057; 20070238285; 20070227578; 20070209699; 20070079866; 20080223436; and 20080271675. Thin film solar cells with a typical thickness of less than 2 μm are produced by depositing the semiconductor materials onto a substrate, generally in multiple layers. Further, connecting wires, metal conductive coatings, and/or metal reflector films may be deposited over the surface of the thin film solar cells to constitute part of the thin film solar cell assembly. The substrate may be formed of glass or a flexible film and may also be referred to as superstrate in those modules in which it faces towards the sunlight. Similarly to the wafer-based solar cell modules, the thin film solar cell assemblies are further encapsulated by, laminated between, or sandwiched between polymeric encapsulants, which are further laminated or sandwiched between protective outer layers. In certain embodiments, the thin film solar cell assembly may be only partially encapsulated by the encapsulant, which means that only the side of the thin film solar cell assembly that is opposite from the substrate (or superstrate) is laminated to a polymeric encapsulant and then a protective outer layer. In such a construction, the thin film solar cell assembly is sandwiched between the substrate (or superstrate) and the encapsulant.

To improve the efficiency of solar cells, a reflecting backsheet layer is often included in the solar cell module to reflect the transmitted light back into the solar cells. In some modules, the back sheets are made of white sheets (such as white Tedlar® sheets) that reflect some light back to the solar cells. In other modules, the back encapsulants are made of pigmented polymeric sheets that function as “reflecting encapsulants”. The adhesion between the polymeric encapsulant and the solar cell assembly is often decreased as the pigmentation level in the encapsulant increases, however. Therefore, there is still a need to develop an encapsulant material that has high reflectivity while maintaining good adhesion strength to the solar cell assemblies.

### SUMMARY OF THE INVENTION

A solar cell module comprising a solar cell assembly and a reflecting back encapsulant, wherein (A) the solar cell assembly comprises one or a plurality of electrically interconnected solar cells and has a front sun-facing side and a back non-sun-facing side and (B) the reflecting back encapsulant comprises a co-extrusion or extrusion coated multilayer sheet, wherein (i) the multilayer sheet comprises a reflecting layer, a first tie layer that is co-extruded or extrusion coated on a first side of the reflecting layer, and optionally a second tie layer that is co-extruded or extrusion coated on a second side of the reflecting layer; (ii) the multilayer sheet has a total thickness of about 2 to about 50 mil (about 51 to about 1270 μm); (iii) the first tie layer comprises a first polymeric material and the second tie layer comprises a second polymeric material, said first and said second polymeric materials having a melting temperature of about 80° C. to about 165° C. and an adhesion to glass of at least about 30 lb/inch when measured with the T-peel test; (iv) the first tie layer has a thickness of about 1 to about 8 mil (about 25 to about 203 μm); (v) the optional second tie layer has a thickness of about 1 to about 35 mil (about 25 to about 889 μm); (vi) the reflecting layer comprises a third polymeric material having a melting temperature between 80° C. and 165° C. and further comprises more than 25 wt % and up to about 90 wt %, based on the total weight of the reflecting layer composition, of a filler having a refractive index above 1.4 or above 1.6 and a mean particle size of 0.1 to 20 μm; (vii) the reflecting layer has a thickness of about 1 to about 35 mil (about 25 to about 889 μm); and (viii) the reflecting back encapsulant is laminated to the back non-sun-facing side of the solar cell assembly with the first tie layer positioned adjacent to the solar cell assembly.

### DETAILED DESCRIPTION OF THE INVENTION

Unless otherwise defined, all technical and scientific terms used herein have the same meaning as commonly understood by one of ordinary skill in the art to which this invention belongs. In case of conflict, the specification, including definitions, will control.

Although methods and materials similar or equivalent to those described herein can be used in the practice or testing of the invention, suitable methods and materials are described herein.

Unless stated otherwise, all percentages, parts, ratios, etc., are by weight.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

The term “about” means that amounts, sizes, formulations, parameters, and other quantities and characteristics include the specific value or end-point referred to; however, they are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or.

The transitional phrase “consisting essentially of” limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that unless otherwise stated the description should be interpreted to also describe such an invention using the terms “consisting essentially of” and “consisting of”.

The articles “a” and “an” may be employed in connection with various elements and components of compositions, processes or structures described herein. This is merely for convenience and to give a general sense of the compositions, processes or structures. Such a description includes “one or at least one” of the elements or components. More specifically, as used herein, the singular articles also include a description of a plurality of elements or components, unless it is apparent from a specific context that the plural is excluded.

The term “or”, as used herein, is inclusive; that is, the phrase “A or B” means “A, B, or both A and B”. More specifically, a condition “A or B” is satisfied by any one of the following: A is true (or present) and B is false (or not present); A is false (or not present) and B is true (or present); or both A and B are true (or present). Exclusive “or” is designated herein by terms such as “either A or B” and “one of A or B”, for example.

When materials, methods, or machinery are described herein with the term “known to those of skill in the art”, “conventional” or a synonymous word or phrase, the term signifies that materials, methods, and machinery that are conventional at the time of filing the present application are encompassed by this description. Also encompassed are materials, methods, and machinery that are not presently conventional, but that will have become recognized in the art as suitable for a similar purpose.

As used herein, the term “copolymer” refers to polymers comprising copolymerized units resulting from copolymerization of two or more comonomers. In this connection, a copolymer may be described herein with reference to its constituent comonomers or to the amounts of its constituent comonomers, for example “a copolymer comprising ethylene and 15 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such.

Finally, the term “solar cell” as used herein includes any article that can convert light into electrical energy. Solar cells useful in the invention include, but are not limited to, wafer-based solar cells (e.g., c-Si or mc-Si based solar cells), thin film solar cells (e.g., a-Si, μc-Si, CdTe, or CI(G)S based solar cells), and organic solar cells.

Described herein is a co-extruded or extrusion coated multilayer sheet that is useful in solar cell modules as a reflecting back encapsulant with diffuse reflection.

The multilayer sheet comprises a reflecting layer and a first tie layer that is co-extruded or extrusion coated on a first side of the reflecting layer. Optionally, the multilayer sheet may also comprise a second tie layer, co-extruded or extrusion coated on a second side of the reflecting layer. In one solar cell module, the multilayer sheet has one tie layer co-extruded or extrusion coated on one side of the reflecting layer and, when incorporated in a solar cell module, the tie layer is positioned next to the solar cell assembly. In another solar cell module, the multilayer sheet may have two tie layers co-extruded or extrusion coated on each side of the reflecting layer and, when incorporated into a solar cell module, one of the two tie layers is positioned next to the solar cell assembly.

The first and optional second tie layers may comprise or may be made from a first and a second polymeric material, respectively, each of which has (i) a melting temperature of about 80° C. to about 165° C., or about 85° C. to about 160° C., or about 90° C. to about 150° C., or about 100° C. to about 135° C. and (ii) an adhesion to glass of at least about 30 lb/inch, or at least about 40 lb/inch, or at least about 50 lb/inch, or about 60 lb/inch when measured by the T-peel test. In the T-peel test, the reflecting multilayer encapsulant is laminated between glass (2 mm thickness) and a back sheet (Tedlar®/PET/Tedlar®). The samples are 15 mm wide and about 10 cm long. The lamination is performed using a Kopp sealer with jaws that are 20 mm wide, available from Willi Kopp e.K. Verpackungs-systeme of Reichenbach/Fils, Germany. The sealing conditions are 140° C. at 3 bar for a period of 10 minutes. The adhesion between the glass and the encapsulant of the laminated sample (glass/encapsulant/backsheet) is measured using an Instron tensile tester, available from Instron Worldwide Headquarters in Norwood, Mass. The glass layer is attached to one clamp and the encapsulant/back sheet layers together are attached to a second clamp of the tensile tester. The pulling speed is 100 mm/min.

When the multilayer sheets comprise both the first and the second tie layers, the first and the second polymeric materials comprised in each of the first and the second tie layers may be the same or different. Each of the first and the second polymeric materials may be independently selected from polyolefins (including polyethylenes (such as ethylene homopolymers and ethylene copolymers) and polypropylenes (such as propylene homopolymers and propylene copolymers), polyurethanes, poly(vinyl butyrals), and combinations of two or more thereof. In addition, in order to maintain good adhesion to glass, when polyethylenes are used as the first and/or second polymeric material, they may be compounded or grafted with silane, or grafted or copolymerized with maleic anhydride. Moreover, when polypropylenes are used as the first and/or second polymeric material, they may be compounded or grafted with silane, or grafted or copolymerized with maleic anhydride.

In one multilayer sheet, the first and/or second polymeric material used in the tie layer is an ethylene copolymer comprising copolymerized units of ethylene and a polar monomer. Suitable polar monomers may include, but are not limited to, vinyl acetates, carboxylic acids such as (meth)acrylic acids (including esters thereof (i.e., acrylates) and salts thereof (i.e., ionomers)), and combinations of two or more thereof. The term “(meth)acrylic acids” is used here to refer to both acrylic acids and methacrylic acids and the term “(meth)acrylates” is used here to refer to both acrylates and methacrylates.

In another multilayer sheet, the first and/or second polymeric material used in the tie layer is an ethylene/vinyl acetate copolymer. Ethylene/vinyl acetate copolymers are well known to one skilled in the art and have been used as encapsulant materials in the solar cell industry. The vinyl acetate comonomer may be present in the ethylene/vinyl acetate copolymers at a level of about 0.1 to about 50 wt %, or about 2 to about 50 wt %, or about 10 to about 40 wt %, or about 15 to about 35 wt %, based on the total weight of the copolymer. Examples of commercially available ethylene/vinyl acetate copolymers include DuPont™ Elvax® PV1400 series resins available from E. I. du Pont de Nemours and Company (DuPont), Wilmington, Del.

In yet another multilayer sheet, the first and/or polymeric material used in the tie layer is an ethylene/carboxylic acid copolymer, which may comprise about 3 to about 30 wt %, or about 4 to about 25 wt %, or about 5 to about 24 wt %, or about 5 to about 23 wt %, of copolymerized units derived from at least one unsaturated carboxylic acid, such as acrylic acids, methacrylic acids, and combinations thereof. The ethylene/carboxylic acid copolymers may further comprise copolymerized units derived from other additional comonomer(s), such as methyl acrylates, methyl methacrylates, butyl acrylates, butyl methacrylates, glycidyl methacrylates, vinyl acetates, and combinations of two or more thereof. Suitable ethylene/carboxylic acid copolymers include those described in and those polymerized as described in U.S. Pat. Nos. 3,404,134; 5,028,674; 6,500,888; and 6,518,365. Examples of commercially available ethylene/carboxylic acid copolymers include those sold by DuPont under the trademark Nucrel®.

Also included in the suitable ethylene/carboxylic acid copolymers are those obtained by copolymerization of ethylene and about 3 to about 20 wt %, or about 6 to about 15 wt %, or about 8 to about 15 wt %, based on the total weight of the copolymer, of a polar monomer selected from the group consisting of monoesters of C₄ to C₈ unsaturated acids having two carboxylic acid groups, diesters of C₄ to C₈ unsaturated acids having two carboxylic acid groups, anhydrides of C₄ to C₈ unsaturated acids having two carboxylic acid groups, and combinations of any two or more thereof. The suitable polar monomers may include, but are not limited to, butenedioic acids (e.g. maleic acid, fumaric acid, itaconic acid and citraconic acid), C₁ to C₂₀ alkyl monoesters of butenedioic acids (e.g., methyl hydrogen maleate, ethyl hydrogen maleate, propyl hydrogen fumarate, and 2-ethylhexyl hydrogen fumarate), C₁ to C₂₀ alkyl diesters of butenedioic acids (e.g., dimethylmaleate, diethylmaleate, dibutylcitraconate, dioctylmaleate, and di-2-ethylhexylfumarate). Such copolymers may also comprise copolymerized units derived from additional comonomer(s), such as, but not limited to, vinyl acetate, alkyl acrylates, alkyl methacrylates, acrylic acids, methacrylic acids, and combinations of two or more thereof. Specific examples of such copolymers useful as the first polymeric material in the tie layer include, but are not limited to, ethylene/maleic acid monoester dipolymers (e.g., ethylene/ethyl hydrogen maleate dipolymer), ethylene/maleic acid monoester/n-butyl methacrylate terpolymers, ethylene/maleic acid monoester/methyl acrylate terpolymers, ethylene/maleic acid monoester/methyl methacrylate terpolymers, ethylene/maleic acid monoester/ethyl methacrylate terpolymers, ethylene/maleic acid monoester/ethyl acrylate terpolymers, and combinations of two or more thereof. Such copolymers are described in U.S. Patent Application Publication No. 2005/0187315 and may be synthesized by random copolymerization in a high-pressure free radical process (see, e.g., U.S. Pat. No. 4,351,931). Further, the first and/or second polymeric material used in the tie layer of the multilayer sheet may also be a blend of such copolymers with an ethylene/vinyl acetate copolymer or an ethylene/alkyl acrylate copolymer or an ethylene/alkyl methacrylate copolymer, as described in U.S. patent application Ser. No. 12/276,846.

In yet another multilayer sheet, the first and/or second polymeric material used in the tie layer is an ethylene/alkyl acrylate copolymer comprising copolymerized units derived from ethylene and copolymerized units derived from an alkyl acrylate, an alkyl methacrylate, or a combination thereof, wherein the alkyl moiety contains from 1 to 8 carbons and may be selected from methyl groups, ethyl groups, and branched or unbranched propyl, butyl, pentyl, and hexyl groups. The polymerized units derived from the alkyl acrylate or alkyl methacrylate comonomers may be present in the ethylene/alkyl acrylate copolymer at a level of about 0.1 to about 45 wt %, or about 5 to about 45 wt %, or about 10 to about 35 wt %, or about 10 to about 28 wt %, based on the total weight of the copolymer. The ethylene/alkyl acrylate copolymers may also comprise up to about 35 wt %, based on the total weight of the copolymer, copolymerized units derived from additional comonomer(s) such as, but not limited to, carbon monoxide, sulfur dioxide, acrylonitrile, maleic anhydride, dimethyl maleate diethyl maleate, dibutyal maleate, dimethyl fumarate, diethyl fumarate, dibutyl fumarate, maleic acid (or salts thereof), maleic acid monoesters (or salts thereof), itaconic acid (or salts thereof), fumaric acid (or salts thereof), fumaric acid monoester (or salts thereof), glycidyl acrylate, glycidyl methacrylate, glycidyl vinyl ether, or combinations of two or more thereof. The ethylene/alkyl acrylate copolymers may be produced by any processes known in the art, for example those using autoclave or tubular reactors. See, e.g., U.S. Pat. Nos. 2,897,183; 3,404,134; 5,028,674; 6,500,888, and 6,518,365. Examples of suitable ethylene/alkyl acrylate copolymers include, but are not limited to, ethylene/acrylate copolymers, ethylene/methyl acrylate copolymers, ethylene/ethyl acrylate copolymers, ethylene/butyl acrylate copolymers, ethylene/n-butyl acrylate copolymers/carbon monoxide terpolymers, ethylene/n-butyl acrylate/glycicyl methacrylate terpolymers, and combinations of two or more thereof. Examples of commercially available ethylene/alkyl acrylate copolymers include those sold by DuPont under the trademark Elvaloy®.

In yet another multilayer sheet, the first and/or second polymeric material may be an ionomer. The term “ionomer” as used herein refers to a polymer that is obtained by partially or fully neutralizing the carboxylic acid groups of an ethylene/carboxylic acid copolymer, for example those described above, with one or more ion-containing bases. In one example, the carboxylic acid groups present in the copolymer may be neutralized to a level of about 5% to about 90%, or about 10 to about 80%, or about 10 to about 70%, or about 10 to about 60%, or about 15 to about 60%. Any ion-containing base that is capable of neutralizing a carboxylic acid may be used to obtain the ionomers. Some preferred ion-containing bases comprise the cation of an alkali metal, an alkaline earth metal, a transition metal, or a combination of two or more of these cations. In some preferred processes, the ionomer is obtained by neutralizing the ethylene/carboxylic acid copolymer with a zinc ion-containing base or a sodium ion-containing base. Alternatively, the ionomer may comprise both sodium cations and zinc cations. To obtain the ionomers used herein, the ethylene/carboxylic acid copolymers may be neutralized by any suitable procedure, such as those described in U.S. Pat. Nos. 3,404,134 and 6,518,365.

Ionomers are advantageously used as tie layers in the multilayer reflecting encapsulant described herein. In a solar cell module, the encapsulant may be in contact with a transparent conductive oxide layer, such as a zinc oxide (ZnO) layer; a tin oxide (Sn₂O₃) layer; an indium tin oxide layer; or a layer of TEC Glass™ available from Pilkington Building Products North America of Toledo, Ohio. Transparent conducting oxide layers may be doped with various elements. For example, zinc oxide may be doped with boron or aluminum to improve its properties, and a tin oxide layer may be doped with fluorine. It is desirable for the interface between the encapsulant and the transparent conductive oxide layer to be stable. Stability increases with the increasing moisture resistance of the layer in contact with the transparent conductive oxide layer. It has now surprisingly been found that the transparent conductive oxide layers are particularly stable when they are laminated in contact with sodium-containing ionomers such as those found in SentryGlas® or in PV5300 encapsulant sheets, available from DuPont.

In yet another multilayer sheet, the first and/or second polymeric material may be a poly(vinyl butyral). Poly(vinyl butyral) is a vinyl resin resulting from the condensation of poly(vinyl alcohol) with butyraldehyde. The poly(vinyl butyral) may be produced by aqueous or solvent acetalization. In a solvent process, acetalization is carried out in the presence of sufficient solvent to dissolve the poly(vinyl butyral) and produce a homogeneous solution at the end of acetalization. The poly(vinyl butyral) is separated from solution by precipitation of solid particles with water, which are then washed and dried. Solvents used are lower aliphatic alcohols such as ethanol. In an aqueous process, acetalization is carried out by adding butyraldehyde to a water solution of poly(vinyl alcohol) at a temperature of about 20° C. to about 100° C., in the presence of an acid catalyst, agitating the mixture to cause an intermediate PVB to precipitate in finely divided form and continuing the agitation while heating until the reaction mixture has proceeded to the desired end point, followed by neutralization of the catalyst, separation, stabilization and drying of the poly(vinyl butyral). For example, poly(vinyl butyral) can be produced as described in U.S. Pat. Nos. 3,153,009 and 4,696,971.

The poly(vinyl butyral) resins may have a weight average molecular weight of about 30,000 Da, or about 45,000 Da, or about 200,000 Da to about 600,000 Da, or about 300,000 Da, as determined by size exclusion chromatography using low angle laser light scattering. The poly(vinyl butyral) may comprise about 12 wt %, or about 14 wt %, or about 15 wt %, to about 23 wt %, or about 21 wt %, or about 19.5 wt %, or about 19 wt % of hydroxyl groups calculated as polyvinyl alcohol (PVOH). The hydroxyl number can be determined according to standard methods, such as ASTM D1396-92 (1998). In addition, the poly(vinyl butyral) may include up to about 10%, or up to about 3% of residual ester groups, calculated as polyvinyl ester, typically acetate groups, with the balance being butyraldehyde acetal. The poly(vinyl butyral) may further comprise a minor amount of acetal groups other than butyral, for example, 2-ethyl hexanal, as described in U.S. Pat. No. 5,137,954.

Plasticizers suitable for the poly(vinyl butyral) tie layers may be any of those that are known within the art (see, e.g., U.S. Pat. Nos. 3,841,890; 4,144,217; 4,276,351; 4,335,036; 4,902,464; 5,013,779; and 5,886,075). Among those commonly used plasticizers are esters of a polybasic acid or a polyhydric alcohol. Examples of suitable plasticizers include, but are not limited to, diesters obtained from the reaction of triethylene glycol or tetraethylene glycol with aliphatic carboxylic acids having from 6 to 10 carbon atoms; diesters obtained from the reaction of sebacic acid with aliphatic alcohols having from 1 to 18 carbon atoms; oligoethylene glycol di-2-ethylhexanoate; tetraethylene glycol di-n-heptanoate; dihexyl adipate; dioctyl adipate; mixtures of heptyl and nonyl adipates; dibutyl sebacate; tributoxyethylphosphate; isodecylphenylphosphate; triisopropylphosphite; polymeric plasticizers, such as, the oil-modified sebacid alkyds; mixtures of phosphates and adipates; mixtures of adipates and alkyl benzyl phthalates; and combinations of two or more of the above. Preferred plasticizers include triethylene glycol di-2-ethylhexanoate, tetraethylene glycol di-n-heptanoate, dibutyl sebacate, and combinations of two or more thereof. More preferred plasticizers include triethylene glycol di-2-ethylhexanoate, tetraethylene glycol di-n-heptanoate, and combinations of two or more thereof. A plasticizer of note is triethylene glycol di-2-ethylhexanoate.

In yet another multilayer sheet, the first and/or second polymeric material may be an ethylene homopolymer or an ethylene copolymer comprising copolymerized units of ethylene and other non-polar α-olefins. In these tie layers, the ethylene homopolymer or the ethylene copolymer is preferably grafted with maleic anhydride groups or further comprises polymerized units of silane groups to maintain sufficient adhesion to the solar cell assemblies and/or the backsheets.

In yet another multilayer sheet, the first and/or second polymeric material may be a polypropylene (including propylene homopolymers and propylene copolymers). The polypropylenes are also preferably grafted with maleic anhydride groups or further comprise polymerized units of silane groups to maintain sufficient adhesion to the solar cell assemblies and/or the backsheets.

The reflecting layer of the multilayer sheet may comprise or be made from a third polymeric material and a filler. The third polymeric material, in turn, may comprise or be made from any polymer or combination of polymers having a melting temperature of about 80° C. to about 165° C., or about 85° C. to about 160° C., or about 90° C. to about 150° C., or about 100° C. to about 135° C. For example, the third polymeric material may be selected from polyolefins (including polyethylenes (such as ethylene homopolymers and ethylene copolymers) and polypropylenes (such as propylene homopolymers and propylene copolymers), polyurethanes, poly(ethylene-co-vinyl acetate), poly(vinyl butyrals), and combinations of two or more thereof.

In one multilayer sheet, the third polymeric material is an ethylene homopolymer. The ethylene homopolymer may be produced by high pressure or low pressure processes. Specific examples of ethylene homopolymers useful as the third polymeric material include, but are not limited to, low density polyethylenes, linear low density polyethylenes, very low density polyethylenes, ultra low density polyethylenes, medium density polyethylenes, high density polyethylenes, metallocene catalyzed polyethylenes, other polyethylenes that are the products of single-site catalysis, and combinations of two or more of these polyethylenes. The linear low density polyethylenes may include very low density polyethylenes, ultra low density polyethylenes, and medium density polyethylene types which are also linear, but, generally, have densities in the range of about 0.916 to about 0.925 g/cm³. The density of the very low density polyethylenes or ultra low density polyethylenes may be in the range of about 0.870 to about 0.915 g/cm³. Many suitable polyethylenes are available commercially and include, for example, DOWLEX™ polyethylene resins from The Dow Chemical Company, Midland, Mich.

In another multilayer sheet, the third polymeric material is an ethylene copolymer comprising copolymerized units of ethylene and α-olefins. Examples of suitable α-olefins are propylene, 1-butene, 1-hexene, 4-methyl-1-pentene, and 1-octene. The ethylene copolymer may also be a copolymer of ethylene and polar monomer, such as those described above, which are also useful as the first polymeric material comprised in the tie layer of the multilayer sheet.

In yet another multilayer sheet, the third polymeric material is a propylene homopolymer or a propylene copolymer comprising copolymerized units of propylene and other αolefin(s). Specific examples of suitable propylene homopolymers and copolymers include, but are not limited to, those described in Polypropylene Handbook: Polymerization, Characterization, Properties, Processing, Applications 3-14, 113-176 (E. Moore, Jr. ed., 1996).

In yet another multilayer sheet, the third polymeric material may also be an ionomer or a poly(vinyl butyral), such as those described above as suitable for use in the tie layers. When the tie layers comprise an ionomer, the third polymeric material preferably also comprises an ionomer.

Fillers suitable for use in the reflecting layer of the multilayer sheet include, but are not limited to, fillers having a refractive index of about 1.4 or above, about 1.6 or above, or about 2 or above, or about 2.5 or above, and a mean particle size of about 0.1 to about 20 μm, or about 0.1 to about 10 μm, or about 0.1 to about 5, or about 0.1 to about 2, or about 0.2 to about 1 μm, or about 0.1 to about 0.5 μm, or about 0.2 to about 0.5 μm. Specific examples of suitable fillers include, without limitation, calcium carbonate, magnesium carbonate, barium carbonate, magnesium sulfate, barium sulfate, calcium sulfate, zinc oxide, magnesium oxide, calcium oxide, titanium oxide, alumina, aluminum hydroxide, hydroxyapatite, silica, mica, talc, kaolin, clay, glass powder, asbestos powder, zeolite, clay silicate, coal fly ash, and combinations of two or more thereof.

In one reflecting layer, the filler is selected from materials that have refractive indices of 1.6 or greater, such as calcium carbonate, barium sulfate, titanium oxide, zinc oxide, mica, glass powder, and combinations of two or more thereof. In another reflecting layer, the filler is titanium oxide, which has a refractive index of 2.5, 2.7 or greater. Suitable grades of titanium oxide are commercially available from DuPont under the trademark Ti-Pure®.

In yet another reflecting layer, the filler is coal fly ash, which has a refractive index of 1.4 to 1.7. Coal fly ash has the advantage of providing improved moisture resistance and improved volume resistivity. Moisture resistance may be important when the third polymeric material comprises poly(ethylene-co-vinyl acetate), for example. This polymer is known to be susceptible to degradation of its properties upon exposure to moisture; however, in combination with coal fly ash, the extent of this degradation is expected to be reduced. Volume resistivity is an important characteristic in encapsulant layers because a reduced volume resistivity is correlated with a reduced tendency for short circuits in the solar cell module.

The filler may be present in the reflecting layer at a level of at least about 4 wt %, at least about 10 wt %, at least about 15 wt %, at least about 25 wt %, greater than 25 wt %, about 28 wt %, at least about 28 wt %, at least about 29 wt %, at least about 30 wt %, at least about 32 wt %, or at least about 35 wt %, based on the total weight of the reflecting layer's composition. In addition, the filler may be present at a level of up to about 90 wt %, up to about 80 wt %, up to about 70 wt %, up to about 60 wt %, up to about 50 wt %, or up to about 40 wt %, based on the total weight of the reflecting layer's composition.

The fillers may be compounded with the third polymeric material via methods that are well known in the art. Alternatively, the fillers may be added into the polymer matrix via commercially obtained filler concentrates or “master batches.” Alternatively, the fillers may be added into the polymer matrix during polymerization.

The multilayer sheet may further comprise additional co-extruded or extrusion coated layers between the tie layer(s) and the reflecting layer. For example, the multilayer sheet may be (i) a bi-layer sheet that comprises a reflecting layer and a tie layer that is co-extruded or extrusion coated on one side of the reflecting layer (tie layer/reflecting layer); (ii) a tri-layer sheet that comprises a reflecting layer, a suitable polymer film layer that is co-extruded or extrusion coated on one side of the reflecting layer, and a tie layer that is co-extruded or extrusion coated on the suitable polymer film layer (tie layer/polymer film/reflecting layer); (iii) a tri-layer sheet that comprises a reflecting layer and two tie layers that are co-extruded or extrusion coated on each side of the reflecting layer, wherein the polymeric materials comprised in the two tie layers may be the same or different (first tie layer/reflecting layer/second tie layer); or (iv) a five-layer sheet that comprises a reflecting layer, two suitable polymer films co-extruded or extrusion coated on each side of the reflecting layer, and two tie layers co-extruded or extrusion coated on each of the two suitable polymer films, wherein the polymeric materials comprised in the two suitable polymer films may be the same or different and the polymeric materials comprised in the two tie layers may be the same or different (first tie layer/first polymer film/reflecting layer/second polymer film/second tie layer).

Furthermore, any of the component sheet or film layers of the multilayer sheet may further comprise suitable additive(s) known in the art. Such additives include, but are not limited to, plasticizers, processing aides, flow enhancing additives, flow reducing additives (e.g., organic peroxides), lubricants, pigments, dyes, optical brighteners, flame retardants, impact modifiers, nucleating agents, antiblocking agents (e.g., silica), thermal stabilizers, hindered amine light stabilizers (HALS), UV absorbers, UV stabilizers, dispersants, surfactants, chelating agents, coupling agents, adhesives, primers, reinforcement additives (e.g., glass fiber), and combinations of two or more thereof. The Kirk Othmer Encyclopedia of Chemical Technology, 5th Edition, John Wiley & Sons (New Jersey, 2004) includes descriptions of these additives and of suitable levels and suitable methods for incorporating the additives into polymer compositions.

In general, however, these optional additives may be present in the sheet or film compositions at a level of about 0.01 to about 15 wt %, or about 0.01 to about 10 wt %, or about 0.01 to about 5 wt %, or about 1 wt %, so long as they neither detract from the basic and novel characteristics of the multilayer sheet nor significantly adversely affect the performance of the multilayer sheet or of the solar cell module comprising the multilayer sheet. Moreover, the incorporation of optional additives into the compositions can be carried out by any suitable process, including, for example, by dry blending, by extruding a mixture of the various constituents, or by a masterbatch technique.

Four notable additives that are useful in the multilayer sheets are thermal stabilizers, UV absorbers, hindered amine light stabilizers, and silane coupling agents. First, thermal stabilizers have been described extensively. Any known thermal stabilizer may be suitable for use in the multilayer sheet. Preferred general classes of thermal stabilizers include, but are not limited to, phenolic antioxidants, alkylated monophenols, alkylthiomethylphenols, hydroquinones, alkylated hydroquinones, tocopherols, hydroxylated thiodiphenyl ethers, alkylidenebisphenols, O-, N- and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid (vitamin C), compounds that destroy peroxide, hydroxylamines, nitrones, thiosynergists, benzofuranones, indolinones, and the like and mixtures thereof. The sheet or film composition may contain any effective amount of thermal stabilizers. Use of a thermal stabilizer is optional and in some instances is not preferred. When thermal stabilizers are used, they may be present in the sheet or film composition at a level of at least about 0.05 wt % and up to about 10 wt %, or up to about 5 wt %, or up to about 1 wt %, based on the total weight of the sheet or film composition.

UV absorbers can be used and have also been extensively described. Any known UV absorber may be suitable for use in the multilayer sheet. Preferred general classes of UV absorbers include, but are not limited to, benzotriazole derivatives, hydroxybenzophenones, hydroxyphenyl triazines, esters of substituted and unsubstituted benzoic acids, and the like and mixtures thereof. The sheet or film composition may contain any effective amount of UV absorbers. Use of a UV absorber is optional and in some instances is not preferred. When UV absorbers are utilized, they may be present in the sheet or film composition at a level of at least about 0.05 wt %, and up to about 10 wt %, or up to about 5 wt %, or up to about 1 wt %, based on the total weight of the sheet or film composition.

Hindered amine light stabilizers (HALS) can be used and are also well known in the art. Generally, hindered amine light stabilizers are secondary, tertiary, acetylated, N-hydrocarbyloxy substituted, hydroxyl-substituted N-hydrocarbyloxy substituted, or other substituted cyclic amines which are characterized by a substantial amount of steric hindrance, generally derived from aliphatic substitution on the carbon atoms adjacent to the amine function. The sheet or film composition may contain any effective amount of hindered amine light stabilizers. Use of hindered amine light stabilizers is optional and in some instances is not preferred. When hindered amine light stabilizers are used, they may be present in the sheet or film composition at a level of at least about 0.05 wt %, and up to about 10 wt %, or up to about 5 wt %, or up to about 1 wt %, based on the total weight of the sheet or film composition.

Examples of silane coupling agents that are useful in the sheet or film compositions include, but are not limited to, γ-chloropropylmethoxysilane, vinyltrimethoxysilane, vinyltriethoxysilane, vinyltris(β-methoxyethoxy)silane, γ-vinylbenzylpropyltrimethoxysilane, N-β-(N-vinylbenzylaminoethyl)-γ-aminopropyl-trimethoxysilane, γ-methacryloxypropyltrimethoxysilane, vinyltriacetoxysilane, γ-glycidoxypropyltrimethoxysilane, γ-glycidoxypropyl triethoxysilane, β-3,4-epoxycyclohexyl)ethyltrimethoxysilane, vinyltrichlorosilane, γ-mercaptopropyl-methoxysilane, γ-aminopropyltriethoxysilane, N-β-(aminoethyl)-γ-aminopropyl-trimethoxysilane, and mixtures of two or more thereof. The silane coupling agents are preferably incorporated in the sheet or film composition at a level of about 0.01 to about 5 wt %, or about 0.05 to about 1 wt %, based on the total weight of the sheet or film composition.

The multilayer sheet may be prepared by a co-extrusion process, or by an extrusion coating process, or by a combination of both types of processes. In one process, the multilayer sheet is prepared by a co-extrusion blown film (or sheet) or cast film (or sheet) process, which utilizes two or more extruders to melt and deliver a steady volumetric throughput of different polymers to a single extrusion head (die). In another process, the multilayer sheet is prepared by an extrusion coating process, which uses a flat die to coat tie layer(s) onto a reflecting sheet layer, or to coat a reflecting layer onto to a first tie sheet, and then a second tie layer onto the reflecting layer, or to coat additional suitable polymeric film(s) on a reflecting sheet layer and then tie layer(s) on the polymeric film(s).

The multilayer sheet may have total thickness of about 2 to about 50 mil (about 51 to about 1270 μm), or about 5 to about 35 mil (about 127 to about 889 μm), or about 5 to about 30 mil (about 127 to about 762 μm), or about 5 to about 25 mil (about 127 to about 635 μm), or about 10 to about 25 mil (about 254 to about 635 μm), provided that the reflecting layer may have a thickness of about 1 to about 35 mil (about 25 to about 889 μm), or about 3 to about 10 mil (about 76 to about 254 μm), or about 3 to about 8 mil (about 76 to about 203 μm), or about 3 to about 6 mil (about 76 to about 152 μm), or about 3 to about 5 mil (about 76 to about 127 μm) and the tie layer that is positioned next to the solar cell assembly in a solar cell module may have a thickness of about 1 to about 8 mil (about 25 to about 203 μm), or about 1 to about 6 mil (about 25 to about 152 μm), or about 1 to about 4 mil (about 25 to about 102 μm), or about 1 to about 2 mil (about 25 to about 51 μm). In those embodiments where two tie layers are incorporated, the tie layer that is positioned opposite from the solar cell assembly (or next to a back sheet) may have a thickness of about 1 to about 35 mil (about 25 to about 889 μm), or about 1 to about 15 mil (about 25 to about 381 μm), or about 1 to about 10 mil (about 25 to about 254 μm), or about 1 to about 8 mil (about 25 to about 203 μm), or about 1 to about 7 mil (about 25 to about 178 μm), or about 1 to about 6 mil (about 25 to about 152 μm), or about 1 to about 5 mil (about 25 to about 127 μm.

If desired, one or both surfaces of any of the component layers of the multilayer sheet may undergo any suitable adhesion enhancing treatment before the co-extrusion or extrusion coating process. This adhesion enhancing treatment may take any form known within the art including, without limitation, flame treatments (see, e.g., U.S. Pat. Nos. 2,632,921; 2,648,097; 2,683,894; and 2,704,382), plasma treatments (see e.g., U.S. Pat. No. 4,732,814), electron beam treatments, oxidation treatments, corona discharge treatments, chemical treatments, chromic acid treatments, hot air treatments, ozone treatments, ultraviolet light treatments, sand blast treatments, solvent treatments, and combinations of two or more thereof. Also, the adhesion strength may be improved by applying an adhesive or primer coating on the surface of the component layer(s). For example, U.S. Pat. No. 4,865,711 describes a film or sheet with improved bondability, which has a thin layer of carbon deposited on one or both surfaces. Other suitable adhesives or primers may include silanes, poly(allyl amine) based primers (see e.g., U.S. Pat. Nos. 5,411,845; 5,770,312; 5,690,994; and 5,698,329), and acrylic based primers (see e.g., U.S. Pat. No. 5,415,942). The adhesive or primer coating may take the form of a monolayer of the adhesive or primer and may have a thickness of about 0.0004 to about 1 mil (about 0.00001 to about 0.03 mm), or preferably, about 0.004 to about 0.5 mil (about 0.0001 to about 0.013 mm), or more preferably, about 0.004 to about 0.1 mil (about 0.0001 to about 0.003 mm).

Further provided herein is a solar cell module comprising a solar cell assembly and a reflecting back encapsulant comprising the multilayer sheet described above, wherein the solar cell assembly further comprises one or a plurality of electrically interconnected solar cells and has a front sun-facing side and a back non-sun-facing side, and wherein the reflecting back encapsulant is laminated to the back non-sun-facing side of the solar cell assembly with the first tie layer positioned next to the solar cell assembly. In one solar cell assembly, the reflecting back encapsulant has one tie layer co-extruded or extrusion coated on one side of the reflecting layer (e.g., a bi-layer sheet) and the reflecting back encapsulant is laminated to the back non-sun-facing side of the solar cell assembly with the tie layer next to the solar cell assembly. In another solar cell assembly, the reflecting back encapsulant comprises two (a first and a second) tie layers co-extruded or extrusion coated on each side of the reflecting layer (e.g., a tri-layer sheet) and the reflecting back encapsulant is laminated to the back non-sun-facing side of the solar cell assembly with one the two tie layers next to the solar cell assembly.

By “laminated”, it is meant that, within a laminated structure, the two layers are bonded either directly (i.e., without any additional material between the two layers) or indirectly (i.e., with additional material, such as interlayer or adhesive materials, between the two layers). In certain solar cell modules, the reflecting back encapsulant is directly bonded to the solar cell assembly.

Also, because the solar cell assemblies have somewhat uneven surfaces with peaks and voids, during the lamination process, the reflecting back encapsulant material will melt or soften to some degree, and will flow around the peaks and fill the voids of the solar cell assembly. In general, however, the reflecting back encapsulant in the final module remains at an average total thickness of about 2 to about 50 mil (about 51 to about 1270 μm), or about 5 to about 35 mil (about 127 to about 889 μm), or about 5 to about 30 mil (about 127 to about 762 μm), or about 5 to about 25 mil (about 127 to about 635 μm), or about 10 to about 25 mil (about 254 to about 635 μm), provided that the reflecting layer may have a thickness of about 1 to about 35 mil (about 25 to about 889 μm), or about 3 to about 10 mil (about 76 to about 254 μm), or about 3 to about 8 mil (about 76 to about 203 μm), or about 3 to about 6 mil (about 76 to about 152 μm), or about 3 to about 5 mil (about 76 to about 127 μm) and the tie layer that is next to the solar cell assembly would also remain at an average thickness of about 1 to about 8 mil (about 25 to about 203 μm), or about 1 to about 6 mil (about 25 to about 152 μm), or about 1 to about 4 mil (about 25 to about 102 μm), or about 1 to about 2 mil (about 25 to about 51 μm).

The reflecting back encapsulant described herein preferably has a light reflectance of about 80% or higher, or about 70% or higher, or about 60% or higher, at wavelengths in the range of about 420 to about 1150 nm. Light reflectance is measured in the range from 200 nm to 1800 nm on 47×47 mm film samples using a spectrophoto-meter model Cary 500 with integrating sphere. Improved reflectance results in improved cell efficiency, compared to prior art back encapsulants. The filler is believed to be primarily responsible for this improved reflectance. In addition, as the reflecting back encapsulant is in multilayer form and comprises un-pigmented tie layers, it also maintains good adhesion to the solar cell assembly and the back sheet.

It has now surprisingly been found that thinner reflecting layers, comprising higher levels of filler, reflect light more efficiently than thicker reflecting layers that comprise a lower level of filler, although the absolute amount of filler is the same in the thinner and the thicker reflecting layers. Accordingly, preferred reflecting layers comprise at least 25 wt % of filler, or about 28 wt % of filler, or more than 28 wt % of filler. In addition, the thickness of the preferred reflecting layers is about 100 to about 300 μm, more preferably about 150 to about 250 μm. Finally, the reflectance of the preferred multilayer encapsulant sheets is at least 0.90, or more preferably at least 0.95, when measured at wavelengths in the range of from 200 nm to 1800 nm using a spectrophotometer model Cary 500 with integrating sphere.

In one solar cell module, the solar cells are wafer-based solar cells and the solar cell assembly has its back non-sun-facing side laminated to the reflecting back encapsulant and its front sun-facing side laminated to a front encapsulant, wherein the front encapsulant comprises any suitable polymeric material, including but not limited to, ethylene/vinyl acetate copolymers, ethylene/acrylic acid copolymers, ethylene/acrylate copolymers, ionomers, poly(vinyl acetals) (e.g., poly(vinyl butyrals)), polyurethanes, poly(vinyl chlorides), polyethylenes (e.g., linear low density polyethylenes), polyolefin block elastomers, silicone elastomers, epoxy resins, and combinations of two or more thereof.

Over the peripheral edges of the solar cell module, the two encapsulant layers may come in contact with each other and form a seal around the edges of the solar cell assembly. The thus-encapsulated solar cell assembly may be further laminated between two protective outer layers (which are also referred to as the front sheet and back sheet). The protective outer layers may be formed of any suitable sheets or films. Suitable sheets include, without limitation, glass sheets, metal sheets such as aluminum, steel, galvanized steel, ceramic plates, or plastic sheets, such as polycarbonates, acrylics, polyacrylates, cyclic polyolefins (e.g., ethylene norbornene polymers), polystyrenes (preferably polystyrenes prepared in the presence of metallocene catalysts), polyamides, polyesters, fluoropolymers, or combinations of two or more thereof. Suitable films include, without limitation metal films, such as aluminum foil, or polymeric films such as those comprising polyesters (e.g., poly(ethylene terephthalate) and poly(ethylene naphthalate)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetates, etc.), cellophane, silicones, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers, etc.), or combinations of two or more thereof. The polymeric film may be non-oriented, or uniaxially oriented, or biaxially oriented. Some specific examples of suitable polymeric films useful here include, but are not limited to, polyester films (e.g., poly(ethylene terephthalate) films), fluoropolymer films (e.g., Tedlar®, Tefzel®, and Teflon® films available from DuPont). Further, the films used herein may be in the form of a multi-layer film, such as a fluoropolymer/polyester/fluoropolymer multilayer film (e.g., Tedlar®/PET/Tedlar® or TPT laminate film available from Isovolta AG., Austria or Madico, Woburn, Mass).

In another solar cell module, the solar cells are thin film solar cells with the light absorbing materials deposited on a superstrate in layers. The superstrate may be made of any suitable transparent material, such as glass, or any of the metal or polymeric sheets or films described above as suitable for use as a protective outer layer.

The thin film solar cells may be single-junction or multi-junction (including tandem junction) thin film solar cells. As the spectrum of solar energy provides photons of varying energies, multi-junction solar cells were developed to have the sunlight pass serially through several solar cell layers. Each separate layer is tailored for efficient conversion to electrical energy of photons of a specific energy level. The multi-junction solar cells are usually constructed with a higher energy gap layer adjacent to the surface through which the light enters the module, and the lower energy gap layers are positioned further into the module. In principle, any types of solar cells known with the art may be useful here, and they may include, but are not limited to, those described in U.S. Pat. Nos. 4,017,332; 4,179,702; 4,292,416; 6,123,824; 6,288,325; 6,613,603; and 6,784,361, U.S. Patent Publication Nos. 2006/0213548; 2008/0185033; 2008/0223436; 2008/0251120; and 2008/0271675; and PCT Patent Application No. WO2004/084282 and 2007/103598.

In the thin film solar cell modules, the side of the thin film solar cell assembly that is opposite from the superstrate may be laminated to the reflecting back encapsulant with the at least one tie layer next to the thin film solar cell assembly, which may be further laminated to a protective outer layer, as described above. In addition, in such thin film solar cell modules, the reflecting back encapsulant may come in contact with the superstrate of the solar cell assembly over the peripheral edges of the solar cell module and form a seal around the edges of the solar cell assembly. Also, when the thin film solar cell module is a glass/glass type of module, the reflecting multilayer back encapsulant may have a relatively greater thickness of about 15 to about 35 mil (about 381 to about 889 μm), while when it is a flexible module, the reflecting multilayer back encapsulant may have a relative lesser thickness of about 5 to about 15 mil (about 127 to about 381 μm).

Yet further provided herein is a solar cell array comprising two or more of the solar cell modules described above.

Yet further provided herein is a process for converting solar energy to electricity comprising the step of exposing a solar cell assembly comprising the reflecting encapsulant described herein to solar radiation.

Yet further provided herein is a process for preparing a solar cell module comprising the reflecting back encapsulant described above. In essence, any suitable lamination process known in the art (such as an autoclave or a non-autoclave process) may be used to prepare the solar cell modules. If desired, one or both surfaces of any of the component layers of the solar cell module may undergo any suitable adhesion enhancing treatment (as described above for the component layers of the multilayer sheet) prior to the lamination process.

For example, in one suitable lamination process, the solar cell assembly is first stacked between a front encapsulant and a reflecting back encapsulant (with both encapsulants in sheet forms) and further between two protective films or sheets, and this assembly is then subject to the lamination process. When the solar cells are thin film solar cells deposited over a superstrate, the solar cell assembly is first laid over a reflecting back encapsulant (in the form of a multilayer sheet and which is laid over a back sheet), before subjecting the assembly to the lamination process.

In another suitable process, the assembly is placed into a bag capable of sustaining a vacuum (a “vacuum bag”), the air is drawn out of the bag by a vacuum line or other means, the bag is sealed while the vacuum is maintained (e.g., at least about 27-28 in Hg (689-711 mm Hg)), and the sealed bag is placed in an autoclave at a pressure of about 150 to about 250 psi (about 11.3 to about 18.8 bar), a temperature of about 130° C. to about 180° C., or about 120° C. to about 160° C., or about 135° C. to about 160° C., or about 145° C. to about 155° C., for about 10 to about 50 min, or about 20 to about 45 min, or about 20 to about 40 min, or about 25 to about 35 min. A vacuum ring may be substituted for the vacuum bag. One type of suitable vacuum bag is described within U.S. Pat. No. 3,311,517. Following the heat and pressure cycle, the air in the autoclave is cooled without adding additional gas to maintain pressure in the autoclave. After about 20 min of cooling, the excess air pressure is vented and the laminates are removed from the autoclave.

Alternatively, the pre-lamination assembly may be heated in an oven at about 80° C. to about 120° C., or about 90° C. to about 100° C., for about 20 to about 40 min. The heated assembly is then passed through a set of nip rolls so that the air in the void spaces between the individual layers may be squeezed out, and the edge of the assembly sealed. The assembly at this stage is referred to as a “pre-press.”

The pre-press may then be placed in an air autoclave where the temperature is raised to about 120° C. to about 160° C., or about 135° C. to about 160° C., at a pressure of about 100 to about 300 psi (about 6.9 to about 20.7 bar), or preferably about 200 psi (13.8 bar). These conditions are maintained for about 15 min to about 60 min, or about 20 min to about 50 min, after which time the air is cooled without any further air being introduced into the autoclave. After about 20 to about 40 min of cooling, the excess air pressure is vented to the atmosphere and the laminated products are removed from the autoclave.

The solar cell modules may also be produced through non-autoclave processes. Such non-autoclave processes are described, e.g., in U.S. Pat. Nos. 3,234,062; 3,852,136; 4,341,576; 4,385,951; 4,398,979; 5,536,347; 5,853,516; 6,342,116; and 5,415,909, U.S. Patent Publication No. 20040182493, European Patent No. EP1235683 B1, and PCT Patent Publication Nos. WO9101880 and WO03057478. Generally, the non-autoclave processes include heating the pre-lamination assembly and the application of vacuum, pressure or both. For example, the assembly may be successively passed through heating ovens and nip rolls.

The following examples are provided to describe the invention in further detail. These examples, which set forth a preferred mode presently contemplated for carrying out the invention, are intended to illustrate and not to limit the invention.

### EXAMPLES

### Examples E1 and E2

Two five-layer cast sheets were prepared by co-extrusion using 3 extruders, all manufactured by Davis Standard, LLC, of Pawcatuck, Conn. The structural details of the two sheets are outlined in Table 1. During the extrusion process, Nucrel®925 was first introduced into an extruder that was equipped with a screw having a diameter of 3.5″ and a length of 105″. The five heating zones were set at 180° C., 200° C., 220° C., 240° C. and 240° C. Surlyn®1702 was introduced into a second extruder that was equipped with a screw having a diameter of 2.5 in diameter and a length of 75 in. The five heating zones of the second extruder were also set at 180° C., 200° C., 220° C., 240° C. and 240° C. For the reflecting (core) layer, pellets of Surlyn®1702 were blended with pellets of Polywhite™ M8493L3 (available from A. Schulman (Germany)) in a cement blender and introduced into the hopper of a third extruder that was equipped with a screw having a diameter of 2.5 in and a length of 75 in. The five heating zones of the third extruder were set at 180° C., 200° C., 220° C., 240° C. and 240° C. In addition, the pipes, feed-bloc, and die were set at 240° C. The co-extruded resins flowed through a flat die that was 800 mm wide, with 0.7 mm distance between the lips, onto a casting roll having a diameter of 700 mm and set at 20° C. This cast sheet (having a width of 500 mm and a length of 50 m) was wound into a roll.

TABLE 1

| Sample | Layer 1 | Layer 2 | Layer 3 | Layer 4 | Layer 5 |
|---|---|---|---|---|---|
| No. | (thickness) | (thickness) | (thickness) | (thickness) | (thickness) |
| E1 | Nucrel ®925^{a} | Surlyn ®1702^{b} | Surlyn ®1702^{b} | Surlyn ®1702^{b} | Nurcel ®925^{a} |
| | (75 μm) | (50 μm) | (60 wt %) and | (50 μm) | (75 μm) |
| | | | TiO₂ | | |
| | | | Concentrate- | | |
| | | | 1^{c} (40 wt %) | | |
| | | | (250 μm) | | |
| E2 | Nucrel ®925^{a} | Surlyn ®1702^{b} | Surlyn ®1702^{b} | Surlyn ®1702^{b} | Nurcel ®925^{a} |
| | (100 μm) | (75 μm) | (60 wt %) and | (75 μm) | (100 μm) |
| | | | TiO₂ | | |
| | | | Concentrate- | | |
| | | | 1^{c} (40 wt %) | | |
| | | | (150 μm) | | |

^{a}Nucrel ®925 is an ethylene/acrylic acid copolymer resin available from DuPont;
^{b}Surlyn ®1702 is an ionomer resin available from DuPont;
^{c}TiO₂ Concentrate-1 is Polywhite M8493L3 from A. Schulman (Germany), which comprises 70 wt % of TiO₂ and 30 wt % of an ethylene/methyl acrylate copolymer resin.

White Tedlar® PV2112 (1 mil thick, available from DuPont) is currently used as a backsheet in solar cell modules. The reflectance of the 5-layer cast film of Example E1 and of the commercially available white Tedlar® PV2112 film was measured, and the results are reported in Table 2. Light reflectance was measured in the range from 200 nm to 1800 nm on 47×47 mm film samples using a spectrophotometer model Cary 500 with integrating sphere. At every wavelength reported in Table 2, the reflectance of the film of Example E1 significantly exceeded that of the Tedlar® PV2112.

TABLE 2

| Film | 500 nm | 750 nm | 1000 nm | 1150 nm |
|---|---|---|---|---|
| E1 | 0.98 | 0.97 | 0.95 | 0.92 |
| Tedlar ® PV2112 | 0.82 | 0.88 | 0.82 | 0.80 |

Moreover, each of the five-layer cast sheets was laminated to a sheet of glass and its adhesion strength to the glass sheet was measured and is reported in Table 3.

During the lamination process, the five-layer cast sheet was first laid over a 2.1 mm thick lite of float glass. This assembly was placed in a polyamide bag set under vacuum of about 200 mbar to draw the air away and then the bagged assembly was placed in an autoclave having a temperature plateau set at 145° C. and sustained for 20 minutes. The entire cycle in the autoclave for heating, plateau, and cooling was about 1 hour.

The laminate samples were then subjected to adhesion tests. In addition, the internal adhesion of the laminates was measured after 500 hours at 75° C., after 1000 hours of damp heat, or after 100 thermal cycles. For “damp heat” conditioning, the laminate sample was placed in a humidity chamber set at 85% RH and 85° C. for 1000 hours. In each thermal cycle, the laminate samples were exposed to temperature extremes of 85° C. and of −40° C. The temperature extremes were maintained for a period of 10 minutes, with ramping rates of 100° C./hour for the cooling and heating portions of the thermal cycle. During the compressive shear strength (CSS) test, a 1×1 inch square sample of the laminate was subjected to a force having an angle of 45 degree to the glass. The Pummel test was done on the laminate with a flat hammer weighing 500 g. The square sample of laminate having a side of 15 cm is maintained at −18° C. for 3 hours prior to the test. The samples are rated from 0 (no glass adhesion to the sample) to 10 (all the glass adheres to the sample) by comparing the pummeled laminates to pictures of standards.

TABLE 3

| CSS | | | Pummel | |
|---|---|---|---|---|
| | Standard | Interface | | |
| psi | deviation | failure | IN | OUT |

Initial Adhesion

| | | | | | |
|---|---|---|---|---|---|
| E1 | 4410.90 | 357.17 | Inside white | 6.0 | 6.0 |
| | | | interlayer | | |
| E2 | 4115.91 | 352.63 | Inside white | 6.0 | 6.0 |
| | | | interlayer | | |

Adhesion after 500 hours @ 75° C.

| | | | | | |
|---|---|---|---|---|---|
| E1 | 4288.83 | 380.86 | Inside white | 6.0 | 6.0 |
| | | | interlayer | | |
| E2 | 4465.86 | 251.17 | Inside white | 6.0 | 6.0 |
| | | | interlayer | | |

Adhesion after 1000 hours damp heat test

| | | | | | |
|---|---|---|---|---|---|
| E1 | 3095.76 | 208.13 | Inside white | 6.0 | 6.0 |
| | | | interlayer | | |
| E2 | 3575.24 | 509.24 | Inside white | 6.0 | 6.0 |
| | | | interlayer | | |

Adhesion after 100 thermal cycles

| | | | | | |
|---|---|---|---|---|---|
| E1 | 4219.58 | 246.66 | Inside white | 6.0 | 6.0 |
| | | | interlayer | | |
| E2 | 4357.90 | 215.16 | Inside white | 6.0 | 6.0 |
| | | | interlayer | | |

### Example 3

A three-layer blown film was prepared by co-extrusion. The three-layer blown film has a structure of “Surlyn®1705-1 (150 μm)/blend of Surlyn®705-1 (75 wt %) and TiO₂ (25 wt %) (150 μm)/Surlyn®1705-1 (450 μm)”, wherein Surlyn®1705-1 was an ionomer resin available from DuPont and the TiO₂ used in the blend is Ti-Pure®R-105 available from DuPont). In preparing the three-layer film, first, 25% by weight of Ti-Pure®R105 was compounded with 75% by weight of Surlyn®705-1 on a Buss kneader. The blown film lined used was manufactured by Windmoeller and Hoelscher (of Lincoln, R.I., and Lengerich, Germany) and had five extruders with screws of 50 mm in diameter and annular dies of 250 mm diameter. During the process, Surlyn®705-1 was introduced into one extruder for the thinner tie layer (150 μm) and into three extruders for the thicker tie layer (450 μm). The extruder temperatures in each zone were set at 160° C., 165° C., 170° C. and 175° C.; the sheet was cooled by internal cooling with air at 17° C.; the blowing ratio was 1.87; and the total output was 224 Kg/hr.

While certain of the preferred embodiments of this invention have been described and specifically exemplified above, it is not intended that the invention be limited to such embodiments. Various modifications may be made without departing from the scope and spirit of the invention, as set forth in the following claims.

What is claimed is:

1. A solar cell module comprising a solar cell assembly and a reflecting back encapsulant, wherein (A) the solar cell assembly comprises one or a plurality of electrically interconnected solar cells and has a front sun-facing side and a back non-sun-facing side and (B) the reflecting back encapsulant comprises a co-extrusion or extrusion coated multilayer sheet, wherein (i) the multilayer sheet comprises a reflecting layer, a first tie layer that is co-extruded or extrusion coated on a first side of the reflecting layer, and optionally a second tie layer that is co-extruded or extrusion coated on a second side of the reflecting layer; (ii) the multilayer sheet has a total thickness of about 2 to about 50 mil (about 51 to about 1270 μm); (iii) the first tie layer comprises a first polymeric material and the second tie layer comprise a second polymeric material, said first and said second polymeric materials having a melting temperature of about 80° C. to about 165° C. and an adhesion to glass of at least about 30 lb/inch when measured with the T-peel test; (iv) the first tie layer has a thickness of about 1 to about 8 mil (about 25 to about 203 μm); (v) the optional second tie layer has a thickness of about 1 to about 35 mil (about 25 to about 889 μm); (vi) the reflecting layer comprises a third polymeric material having a melting temperature between 80° C. and 165° C. and further comprises greater than 25 wt % and up to 90 wt %, based on the total weight of the reflecting layer composition, of a filler having a refractive index above 1.4 and a mean particle size of 0.1 to 20 μm; (vii) the reflecting layer has a thickness of about 1 to about 35 mil (about 25 to about 889 μm); and (viii) the reflecting back encapsulant is laminated to the back non-sun-facing side of the solar cell assembly with the first tie layer positioned adjacent to the solar cell assembly.

2. The solar cell module of claim 1, wherein the first polymeric material is selected from the group consisting of polyolefins, polyurethanes, poly(vinyl butyrals), and combinations of two or more thereof.

3. The solar cell module of claim 1, wherein the first polymeric material is an ethylene copolymer comprising copolymerized units of ethylene and a polar monomer.

4. The solar cell module of claim 1, wherein the first polymeric material is selected from the group consisting of ethylene/vinyl acetate copolymers, ethylene/acrylic acid copolymers, ethylene/methacrylic acid copolymers, ethylene/acrylate copolymers, ethylene/methacrylate copolymers, ionomers, copolymers of ethylene and monoester, diester, or anhydride of C₄-C₈ unsaturated acids having two carboxylic acid groups, and combinations of two or more thereof.

5. The solar cell module of claim 1, wherein the first polymeric material and the second polymeric material are the same.

6. The solar cell module of claim 1, wherein the first polymeric material and the second polymeric material are different.

7. The solar cell module of claim 1, wherein the third polymeric material is selected from the group consisting of polyolefins, polyurethanes, poly(vinyl butyrals), and combinations of two or more thereof.

8. The solar cell module of claim 1, wherein the third polymeric material is selected from the group consisting of ethylene homopolymers, ethylene copolymers, propylene homopolymers, propylene copolymers, and combinations of two or more thereof.

9. The solar cell module of claim 1, wherein the third polymeric material is an ethylene copolymer selected from the group consisting of ethylene/vinyl acetate copolymers, ethylene/acrylic acid copolymers, ethylene/methacrylic acid copolymers, ethylene/acrylate copolymers, ethylene/methacrylate copolymers, ionomers, copolymers of ethylene and monoester, diester, or anhydride of C₄-C₈ unsaturated acids having two carboxylic acid groups, and combinations of two or more thereof.

10. The solar cell module of claim 1, wherein the filler is selected from the group consisting of calcium carbonate, magnesium carbonate, barium carbonate, magnesium sulfate, barium sulfate, calcium sulfate, zinc oxide, magnesium oxide, calcium oxide, titanium oxide, alumina, aluminum hydroxide, hydroxyapatite, silica, mica, talc, kaolin, clay, glass powder, asbestos powder, zeolite, clay silicate, coal fly ash and combinations of two or more thereof.

11. The solar cell module of claim 8, wherein the filler is titanium oxide that has a refractive index of 2.5 or higher.

12. The solar cell module of claim 1, wherein the filler is present in the reflecting layer composition at a level of 28 wt % to 90 wt %.

13. The solar cell module of claim 1, wherein, the multilayer sheet has a total thickness of about 5 to about 35 mil (about 127 to about 889 μm); the reflecting layer has a thickness of about 3 to about 8 mil (about 76 to about 203 μm), the first tie layer has a thickness of about 1 to about 2 mil (about 25 to about 51 μm).

14. The solar cell module of claim 1, wherein the reflecting back encapsulant has a reflectance of 80% or higher in the range of wavelengths between 420 nm and 1150 nm.

15. The solar cell module of claim 1, wherein the reflecting back encapsulant does not comprise the optional second tie layer.

16. The solar cell module of claim 1, wherein the multilayer sheet comprises the second tie layer co-extruded or extrusion coated on the second side of the reflecting layer.

17. The solar cell module of claim 1, wherein the multilayer sheet is prepared by a co-extrusion process.

18. The solar cell module of claim 1, wherein the multilayer sheet is prepared by an extrusion coating process.

19. The solar cell module of claim 1, which further comprises a back sheet laminated to the reflecting back encapsulant, wherein the back sheet is selected from the group consisting of (i) glass sheets, (ii) polymeric sheets, (iii) polymeric films, (iv) metal sheets, and (v) ceramic plates, and wherein the polymeric sheets comprise a polymer selected from the group consisting of polycarbonates, acrylics, polyacrylates, cyclic polyolefins, polystyrenes, polyamides, polyesters, fluoropolymers, and combinations or two or more thereof; and the polymeric films comprise a polymer selected from the group consisting of polyesters, polycarbonates, polyolefins, norbornene polymers, polystyrenes, styrene-acrylate copolymers, acrylonitrile-styrene copolymers, polysulfones, nylons, polyurethanes, acrylics, cellulose acetates, cellophanes, poly(vinyl chlorides), fluoropolymers, and combinations of two or more thereof.

20. The solar cell module of claim 1, wherein the solar cell(s) are wafer-based solar cells selected from the group consisting of crystalline silicon (c-Si) and multi-crystalline silicone (mc-Si) based solar cells.

21. The solar cell module of claim 19, which further comprises a front encapsulant laminated to the front sun-facing side of the solar cell assembly and a front sheet laminated to the front encapsulant, wherein the front encapsulant comprises a polymeric material selected from the group consisting of ethylene/vinyl acetate copolymers, ethylene/acrylic acid copolymers, ethylene/acrylate copolymers, ionomers, poly(vinyl acetals), polyurethanes, poly(vinyl chlorides), polyethylenes, polyolefin block elastomers, silicone elastomers, epoxy resins, and combinations of two or more thereof, and wherein the front sheet (i) glass sheets, (ii) polymeric sheets comprising a polymer selected from the group consisting of polycarbonates, acrylics, polyacrylates, cyclic polyolefins, polystyrenes, polyamides, polyesters, fluoropolymers, and combinations of two or more thereof, and (iii) polymeric films comprising a polymer selected from the group consisting of polyesters, polycarbonate, polyolefins, norbornene polymers, polystyrene, styrene-acrylate copolymers, acrylonitrile-styrene copolymers, polysulfones, nylons, polyurethanes, acrylics, cellulose acetates, cellophane, poly(vinyl chlorides), fluoropolymers, and combinations of two or more thereof.

22. The solar cell module of claim 1, wherein (a) the solar cells are thin film solar cells selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductors based solar cells; (b) the solar cell assembly comprises a superstrate upon which the thin film solar cells are deposited; and (c) the superstrate is positioned such that the superstrate is on the front sun-facing side of the solar cell assembly.
